(19) United States
(12) Patent Application Publication
(10) Pub. No.: US 2021/0223644 A1
(43) Pub. Date: Jul. 22, 2021

(54) THIN FILM TRANSISTOR AND MANUFACTURING METHOD THEREOF, ARRAY SUBSTRATE AND DISPLAY DEVICEICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Jun WU, Beijing (CN); Qi SANG, Beijing (CN); Jianjun WANG, Beijing (CN)

(21) Appl. No.: 16/096,013

(22) PCT Filed: Mar. 29, 2018
(86) PCT No.: PCT/CN2018/081128

§ 371 Date: Oct. 24, 2018

(30) Foreign Application Priority Data
May 27, 2017 (CN) 201710392950.7

(51) Int. Cl. G02F 1/1362; G02F 1/1368; G02F 1/1343; H01L 27/12

(52) U.S. Cl. CPC G02F 1/136236; G02F 1/1368; H01L 27/1288; G02F 1/13439; G02F 1/134363; G02F 1/134318

(57) ABSTRACT

A thin film transistor and a manufacturing method thereof, an array substrate and a display device are provided. The thin film transistor includes a first electrode, a gate electrode, an active layer, a source/drain electrode and a second electrode. The source/drain electrode is connected with the active layer, the first electrode is provided oppositely to the second electrode; the second electrode is provided in the same layer as the source/drain electrode; and the second electrode and the source/drain electrode are formed in a single patterning process.

### CROSS REFERENCE TO RELATED APPLICATIONS

The present application claims the priority of the Chinese Patent Application No. 201710392950.7 entitled “Thin Film Transistor and Manufacturing Method Thereof, Array Substrate and Display Device” filed on May 27, 2017 with CNIPA, which is incorporated herein by reference in its entirety.

### TECHNICAL FIELD

Embodiments of the present disclosure relate to a thin film transistor and a manufacturing method thereof, an array substrate and a display device.

### BACKGROUND

Advanced Super Dimension Switch (ADS) type liquid crystal display panels are widely applied in display devices for their advantages, such as wide viewing angle, high transmission and high definition.

### SUMMARY

Embodiments of the present disclosure provide a thin film transistor and a manufacturing method thereof, an array substrate and a display device.

At least one embodiment of the present disclosure provides a thin film transistor, comprising: a first electrode, a gate electrode, an active layer, a source/drain electrode and a second electrode. The source/drain electrode is connected with the active layer, the first electrode is provided oppositely to the second electrode; and the second electrode is provided in a same layer as the source/drain electrode.

For example, the second electrode and the source/drain electrode include a same material.

For example, the second electrode and the source/drain electrode both include metal.

For example, the first electrode is provided between the base substrate and the second electrode, the first electrode is a plate electrode or a slit electrode, and the second electrode is a slit electrode.

For example, when the first electrode is a plate electrode, the second electrode is a slit electrode, a slit direction of the slit electrode is along a long side of the plate electrode; or a slit direction of the slit electrode is along a short side of the plate electrode.

For example, the source/drain electrode has a thickness different from that of the second electrode.

For example, the source/drain electrode has a thickness of 0.35 μm˜0.4 μm; and the second electrode has a thickness of 0.04 μm˜0.07 μm.

For example, the first electrode is a common electrode, and the second electrode is a pixel electrode; the first electrode and the gate electrode are provided on the base substrate and are connected with each other, and an insulating layer is provided on the first electrode and the gate electrode; and the active layer, the source/drain electrode and the second electrode are provided on the insulating layer respectively, and the second electrode is connected with the source/drain electrode.

For example, the first electrode is a pixel electrode, and the second electrode is a common electrode; the first electrode and the gate electrode are provided on the base substrate and an insulating layer is provided on the first electrode and the gate electrode; a part of the insulating layer that corresponds to the first electrode is provided with a first via hole, and a part of the insulating layer that corresponds to the second electrode is provided with a second via hole; and the active layer, the source/drain electrode and the second electrode are provided on the insulating layer, respectively, the source/drain electrode is connected with the first electrode through the first via hole, and the second electrode is connected with the gate electrode through the second via hole.

At least one embodiment of the present application also provides a manufacturing method of thin film transistor for manufacturing the thin film transistor, comprising forming a second electrode and a source/drain electrode by a single patterning process.

For example, the second electrode and the source/drain electrode are formed in a single patterning process with a half tone mask.

For example, the first electrode is a common electrode, and the second electrode is a pixel electrode; the manufacturing method of thin-film transistor further comprises: providing a base substrate on which a first electrode and a gate electrode is formed respectively to allow the first electrode and the gate electrode to be connected with each other; forming an insulating layer on the gate electrode and forming an active layer on the insulating layer; and forming a source/drain electrode and a second electrode by a single patterning process on the active layer and the insulating layer respectively to allow the source/drain electrode and the active layer to be connected with each other and the second electrode and the source/drain electrode to be connected to each other.

For example, the first electrode is a pixel electrode, and the second electrode is a common electrode; the manufacturing method of thin-film transistor further comprises: providing a base substrate on which a first electrode and a gate electrode are formed respectively and forming an insulating layer on the first electrode and the gate electrode; forming a first via hole in a part of the insulating layer that corresponds to the first electrode, and forming a second via hole in a part of the insulating layer that corresponds to the second electrode; and forming an active layer on the insulating layer and forming a source/drain electrode and a second electrode on the active layer and the insulating layer by a single patterning process respectively to allow the source/drain electrode to be connected with the active layer, and allow the source/drain electrode to be connected with the first electrode through the first via hole and the second electrode to be connected with the gate electrode through the second via hole.

At least one embodiment of the present application also provides an array substrate comprising the thin film transistor.

At least one embodiment of the present application also provides a display device comprising the array substrate.

### BRIEF DESCRIPTION TO THE DRAWINGS

Embodiments of the present disclosure will be described in more detail below with reference to accompanying drawings to allow an ordinary skill in the art to more clearly understand embodiments of the present disclosure, in which:

FIG. 1 is a top view of a thin film transistor structure;

FIG. 2 is a top view of a thin film transistor structure provided in an embodiment of the present disclosure;

FIG. 3 is a top view of a thin film transistor structure provided in another embodiment of the present disclosure;

FIG. 4 is a top view of a thin film transistor structure provided in yet another embodiment of the present disclosure;

FIG. 5 is a schematically sectional view along A-A of the thin film transistor provided in FIG. 3;

FIG. 6 is a schematically sectional view along A-A′ of the thin film transistor provided in FIG. 4;

FIG. 7 is a schematically sectional view along B-B′ of the thin film transistor provided in FIG. 4;

FIG. 8 is an electro-optical control characteristics diagram of the liquid crystal display (LCD) screen in which the thin film transistor provided in embodiments of the present disclosure is included;

FIG. 9 is an response-characteristic diagram of the LCD screen in which the thin film transistor provided in embodiments of the present disclosure is included;

FIG. 10 is a flow chart I of a manufacturing method of a thin film transistor provided in an embodiment of the present disclosure; and

FIG. 11 is a flow chart II of a manufacturing method of a thin film transistor provided in an embodiment of the present disclosure.

### DETAILED DESCRIPTION

To further demonstrate the thin film transistor and the manufacturing method thereof, the array substrate and the display device, technical solutions of the embodiments will be described in a clearly and fully understandable way in connection with the drawings related to the embodiments of the disclosure. It is apparent that the described embodiments are just a part but not all of the embodiments of the disclosure. Based on the described embodiments herein, a person of ordinary skill in the art can obtain other embodiment(s), without any creative work, which shall be within the scope of the disclosure.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present application, are not intended to indicate any sequence, amount or importance, but for distinguishing various components. Also, the terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” “left,” “right,” or the like are only used to indicate relative position relationship, and when the absolute position of the object which is described is changed, the relative position relationship may be changed accordingly.

Advanced Super Dimension Switch (ADS) technology improves liquid crystal operation efficiency and transmission efficiency by forming a multi-dimensional electric field with an electric field formed at edges of slit electrodes and an electric field formed between the slit electrode layer and the slab-like electrode layer in the same plane such that liquid crystal molecules of all orientations between slit electrodes and directly above the electrodes in liquid crystal cells can undergo rotation, so that the working efficiency of the liquid crystal and the light transmission are improved. ADS technology can improve the image quality of TFT-LCD products to allow the TFT-LCD product to have advantages, such as high resolution, high transmission, low power consumption, wide viewing angle, high aperture ratio, low chromatic aberration and no push Mura.

Referring to FIG. 1, the manufacturing process of thin film transistors in ADS liquid crystal display panels is as follows: forming common electrodes 2 and gate electrodes 3 on the base substrate 1 by a first patterning process and forming an insulating layer on the common electrodes 2 and the gate electrodes 3; then forming an active layer and sources/drain electrode 4 by a second patterning process on the insulating layer; thereafter, forming a passivation layer on the active layer and the sources/drain electrode 4 and forming a via hole in the passivation layer by a third patterning process in order to form an electrical connection between a pixel electrode 5 and the sources/drain electrode 4 through the via hole; and finally forming the pixel electrode 5 on the passivation layer by a fourth patterning process. At least four patterning processes need to be implemented in the manufacturing of thin film transistors in ADS liquid crystal display panels.

The inventors have noticed that, since each patterning process needs multiple steps, such as applying photoresist, soft baking, aligning and exposing, post baking, developing, etching and detecting, which make the forming process for thin film transistors complex and result in low efficiency of manufacturing thin film transistors.

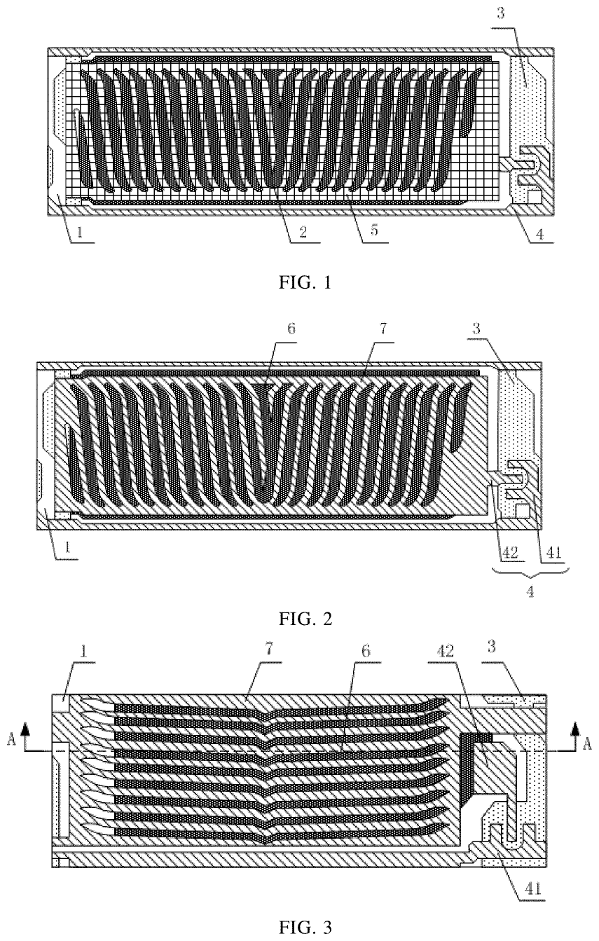

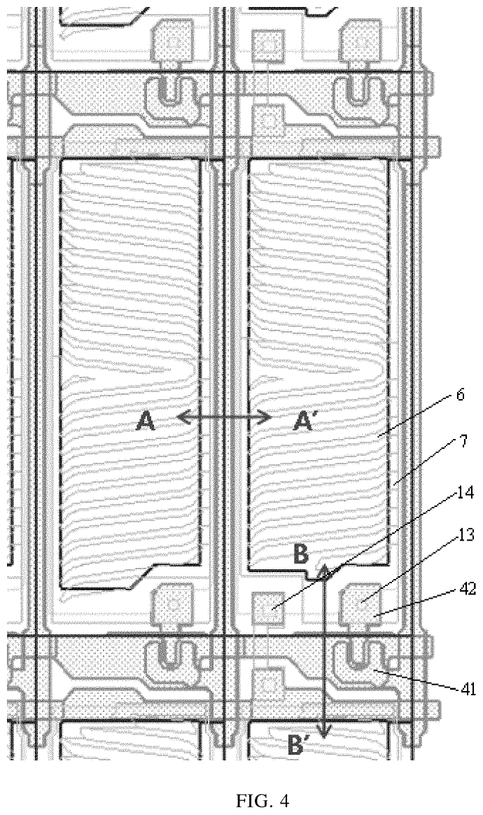

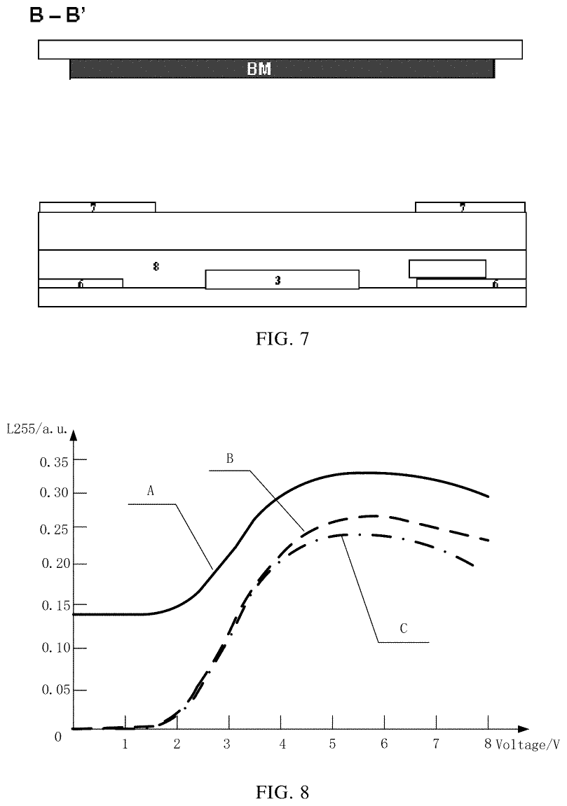

Referring to FIGS. 2, 3 and 4-7, the thin film transistor provided in an embodiment of the present disclosure includes a first electrode 6, a gate electrode 3, an active layer 10, a source/drain electrode 4 and a second electrode 7. The source/drain electrode 4 is connected with the active layer 10, the first electrode 6 is disposed oppositely to the second electrode 7 and the second electrode 7 is disposed in the same layer as the source/drain electrode 4.

For example, the first electrode 6 refers to the electrode disposed on the base substrate 1 while the second electrode 7 refers to the electrode disposed in the same layer as the source/drain electrode 4 and apart from the base substrate 1. The first electrode 6 being disposed oppositely to the second electrode 7 refers to the orthogonal projection of the first electrode 6 on the base substrate 1 overlapping or partially overlapping the orthogonal projection of the second electrode 7 on the base substrate 1. The first electrode 6 is made of Indium Tin Oxide (ITO) while the second electrode 7 is made of the same material as that of the source/drain electrode 4, for example. For example, the second electrode 7 and the source/drain electrode 4 are made of metal material, such as Aluminum, or Copper. The base substrate is a substrate made of glass, quartz, or plastic material, for example.

With the above-described implementation process, in the thin film transistor provided in the present embodiment, the second electrode 7 and the source/drain electrode 4 are disposed in the same layer and made of a conductive material, such that the second electrode 7 and the source/drain electrode 4 may be formed in a single patterning process without forming the passivation layer between the source/drain electrode 4 and the second electrode 7 and forming via holes in the passivation layer by a single patterning process. In this way, the thin film transistor provided in the embodiments of the present disclosure can reduce the number of patterning processes in its manufacturing process, simplify the manufacturing process thereof and improve the manufacturing efficiency.

In the thin film transistor provided in the embodiments of the present disclosure, the second electrode 7 and the source/drain electrode 4 are disposed in the same layer. While the source/drain electrode is generally formed as integrated with the data signal lines, which allows the second electrode 7, the source/drain electrode 4 and the data signal lines 11 to be formed in a single patterning process, allowing no alignment error to occur between the second electrode 7 and the data signal lines, that is, a higher alignment accuracy between the second electrode 7 and the data signal lines is achieved. The reason is in that there is an alignment error for one alignment between a conventional SD mask and Glass, and there is another alignment error for another alignment between the ITO mask and Glass, and in the present embodiment, the overlapping error between the second electrode 7 and the source/drain electrode 4 may be canceled by forming the second electrode 7 and the source/drain electrode 4 at the same time. In this way, while forming a plurality of thin film transistors on the base substrate 1, the data signal line between two adjacent thin film transistors may be kept at the same distance from the second electrodes 7 in these two thin film transistors, which allows the coupling capacitances formed between the data signal line and the two adjacent thin film transistors to be the same, avoiding data signal cross-talk due to different coupling capacitances, which is beneficial for improving display quality of the display device in which the thin film transistors are included.

In the above-described embodiment, the first electrode 6 and the second electrode 7 may have the same or different shapes. Exemplarily, the first electrode 6 is disposed on the base substrate 1 as a plate electrode or a slit electrode; while the second electrode 7 is disposed apart from the base substrate 1, and for example, it is also a slit electrode. When the first electrode 6 and/or the second electrode 7 are/is slit electrode(s), the slit direction of slit electrodes may be designed as desired.

In the embodiment, when the first electrode 6 is a plate electrode and the second electrode 7 is a slit electrode, the slit direction of slit electrode is along the long side of the plate electrode or along the short side of the plate electrode. For example, the orthogonal projection of the plate electrode on the base substrate 1 has a rectangle-like shape and the slit direction of the slit electrode may be the direction as shown in FIG. 2 while being along the short side of the plate electrode; and the slit direction of the slit electrode may be the direction as shown in FIG. 3 while being along the long side of the plate electrode. As can be known by comparing FIGS. 2 and 3, as compared to the arrangement in which the slit direction of the slit electrode is along the short side of the plate electrode, in the second electrode 7 with the same area, disposing the slit direction of the slit electrode along the long side of the plate electrode can fully use the planer space of the second electrode 7, reasonably arrange opening positions of multiple sets of slits, which allows the multiple sets of slits can occupy more space in the second electrode, improving the aperture ratio of the display device in which the thin film transistors are included.

It is also to be noted that the source/drain electrode 4 has a thickness different from that of the second electrode 7 although they are disposed in the same layer. Generally, the source/drain electrode 4 is configured to transfer data signals and therefore should have a certain thickness such that the source/drain electrode 4 has a resistance value to accurately transfer data signals, while the second electrode 7 is a slit electrode and is generally located in an area corresponding to liquid crystal. If the second electrode 7 has a large thickness, a large segment difference will occur at edges of the slit opening of the second electrode 7. In this way, when an alignment layer for aligning liquid crystal is formed on the second electrode 7, it is difficult to achieve uniform alignment friction in the area of the alignment layer that corresponds to the segment difference, which tends to result in a poor alignment of the alignment layer and affect a normal display of the liquid crystal display device. So, a small thickness is selected for the second electrode 7. Exemplarily, the source/drain electrode 4 has a thickness of 0.35 μm˜0.4 μm, while the second electrode 7 has a thickness of 0.04 μm˜0.07 μm.

It is to be noted that, the first electrode may serve as a common electrode or a pixel electrode. When the first electrode 6 serves as a common electrode, the corresponding second electrode 7 serves as a pixel electrode, at this point, the gate electrode 3 is connected with the first electrode 6 while the source/drain electrode 4 is connected with the second electrode 7. When the first electrode 6 serves as a pixel electrode, the corresponding second electrode 7 serves as a common electrode, at this point, the gate electrode 3 is connected with the second electrode 7 while the source/drain electrode 4 is connected with the first electrode 6.

To explain the structure of the corresponding thin film transistor when the first electrode 6 is the common electrode or the pixel electrode more clearly, two specific thin film transistor structures will be listed below and will be described in detail in Embodiment I and Embodiment II respectively.

### Embodiment I

Referring to FIG. 2, the thin film transistor is commonly used in ADS liquid crystal display panels, wherein the first electrode 6 is the common electrode, and the second electrode 7 is the pixel electrode. The first electrode 6 and the gate electrode 3 are disposed in the same layer on the base substrate 1 and are connected with each other; and an insulating layer is provided on the first electrode 6 and the gate electrode 3. An active layer 10, a source/drain electrode 4 and a second electrode 7 are provided on the insulating layer, and the source/drain electrode 4 is connected with the active layer 10 and the second electrode 7 respectively.

It is understood that the source/drain electrode 4 generically includes a source electrode and a drain electrode, which may be interchangeable depending on types of the thin film transistor. In this embodiment, the source electrode 41 serves as the signal input end of the thin film transistor and is connected with the data signal line, and the drain electrode 42 servers as the signal output end of the thin film transistor and is connected with the pixel electrode directly.

### Embodiment II

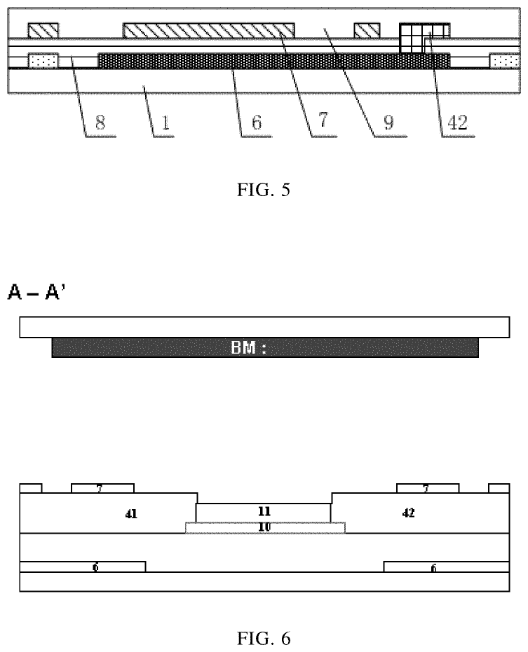

Referring to FIGS. 3 and 5, the thin film transistor is commonly used in high aperture advanced super dimension switch (HADS) liquid crystal display panels, wherein the first electrode 6 serves as the pixel electrode, the second electrode 7 servers as the common electrode. The first electrode 6 and the gate electrode 3 are provided on the base substrate 1 respectively and an insulating layer 8 is provided on the first electrode 6 and the gate electrode 3. A first via hole 13 is provided in a part of the insulating layer 8 that corresponds to the first electrode 6, and a second via hole 14 is provided in a part of the insulating layer 8 that corresponds to the gate electrode 3. An active layer 10, a source electrode 41, a drain electrode 42 and a second electrode 7 are disposed on the insulating layer 8. The drain electrode 42 is connected with the first electrode 6 through the first via hole 13, and the second electrode 7 is connected with the gate electrode 3 through the second via hole 14.

To explain clearly the effect of the material of the second electrode 7 in the above-described embodiment on the electro-optical control characteristics of thin film transistors, an example in which the thin film transistor is applied in an LCD screen will be described in detail below.

FIG. 8 is an electro-optical control characteristics diagram of the LCD screen in which the thin film transistor provided in embodiments of the present disclosure is included. When the second electrode 7 in the thin film transistor is made of an aluminum alloy, the electro-optical control characteristics of the LCD screen in which the thin film transistor is included under the reflection mode is as shown by curve A, and the electro-optical control characteristics of the LCD screen in which the thin film transistor is included under the transmission mode is as shown by curve C; and when the second electrode 7 in the thin film transistor is made of ITO, the electro-optical control characteristics of the LCD screen in which the thin film transistor is included under the reflection mode and the transmission mode are as shown by curve B.

As shown by comparing curves A, B and C in FIG. 8, when the maximum control voltage of the LCD screen is 5.6V, if the second electrode 7 is made of an aluminum alloy, the maximum luminance L255 of the LCD screen in which the thin film transistor is included under the reflection mode is 0.32a.u., while the maximum luminance L255 of the LCD screen in which the thin film transistor is included under the transmission mode is 0.24a.u; and if the second electrode 7 is made of ITO, the maximum luminance L255 of the LCD screen in which the thin film transistor is included under the reflection mode and the transmission mode are both 0.27a.u. In this way, when the second electrode 7 provided in an embodiment of the present disclosure is made of an aluminum alloy, the electro-optical control characteristics of the LCD screen in which the thin film transistor is included under the reflection mode is better than that of the LCD screen when the second electrode 7 is made of ITO material; while when the second electrode 7 provided in an embodiment of the present disclosure is made of an aluminum alloy, the electro-optical control characteristics of the LCD screen in which the thin film transistor is included under the transmission mode is slightly lower than that of the LCD screen when the second electrode 7 is made of ITO material, but the different is not too much, which can also satisfy the display requirement of the LCD screen in which the thin film transistor is included under the transmission mode.

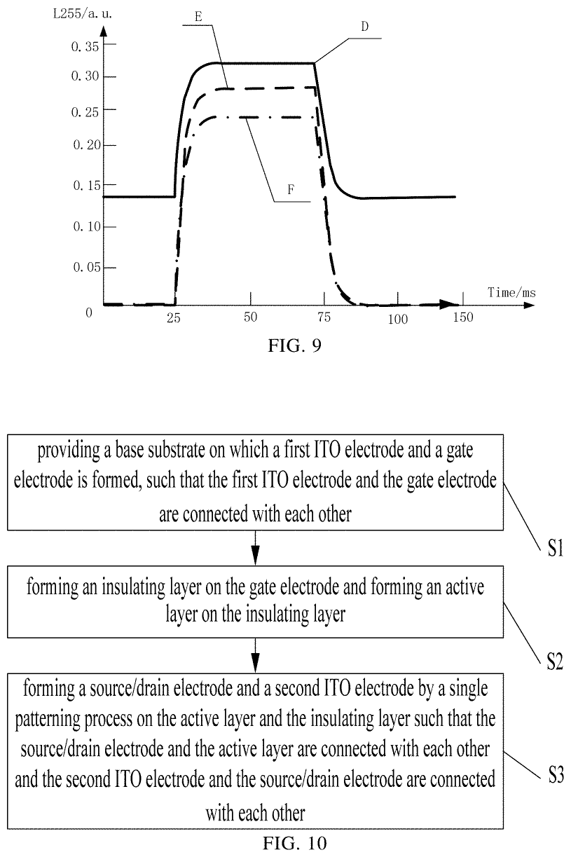

FIG. 9 is a response-characteristic diagram of the LCD screen in which the thin film transistor provided in embodiments of the present disclosure is included. When the second electrode 7 in the thin film transistor is made of an aluminum alloy, the response characteristics graph of the LCD screen in which the thin film transistor is included under the reflection mode is as shown by curve D and the response characteristics graph of the LCD screen in which the thin film transistor is included under the transmission mode is as shown by curve F. When the second electrode 7 in the thin film transistor is made of ITO material, the response characteristics graphs of the LCD screen in which the thin film transistor is included under the reflection mode and the transmission mode are both as shown by curve E.

As shown by comparing curves D, E and F in FIG. 9, if the second electrode 7 is made of an aluminum alloy, the response time of the LCD screen in which the thin film transistor is included under the reflection mode and the transmission mode are both 25.0 ms, while if the second electrode 7 is made of ITO, the response time of the LCD screen in which the thin film transistor is included under the reflection mode and the transmission mode are both 25.1 ms. In this way, whether the second electrode 7 is made of an aluminum alloy or ITO material has little effect on the response time of the LCD screen in which the thin film transistor is included under the reflection mode and the transmission mode and the two times are close. The response time of the LCD screen in which the thin film transistor is included is slightly shorter when the second electrode 7 is made of the aluminum alloy.

When the thin film transistor provided in the embodiments of the present disclosure in which the second electrode 7 is made of the aluminum alloy is applied in a LCD screen, it has a greater advantage than the thin film transistor in which the second electrode 7 is made of the ITO material.

In the thin film transistor provided in embodiments of the present disclosure, the second electrode and the source/drain electrode are disposed in the same layer and made of conductive material such that the second electrode and the source/drain electrode may be formed in a single patterning process without forming a passivation layer between the source/drain electrode and the second electrode and forming via holes in the passivation layer by one patterning process. In this way, the thin film transistor provided in embodiments of the present disclosure can reduce the number of patterning processes used in its manufacturing process, simplifying the manufacturing process thereof and improving the manufacturing efficiency.

An embodiment of the present disclosure also provides a method for manufacturing the thin film transistor provided in the above-described embodiments including forming a second electrode and a source/drain electrode by a single patterning process.

For example, the material of the second electrode and the material of the source/drain electrode may be the same or different. If the second electrode and the source/drain electrode are made of the same material, e.g. metal, it is possible to form the second electrode and the source/drain electrode simply by a single mask process after depositing the metal film; while if the second electrode and the source/drain electrode are made of different materials, for example, the second electrode is ITO and the source/drain electrode is metal, an ITO film and a metal film are deposited one over another, or the ITO film and the metal film are deposited in separate areas and then the second electrode and the source/drain electrode are formed by one mask process.

The manufacturing method of thin film transistor provided in the embodiment of the present disclosure has the same beneficial effects as that provided in the above-described technical proposals and will not be described any more here.

It is to be noted that, in the manufacturing method of thin film transistor provided in the embodiment of the present disclosure, while the second electrode and the source/drain electrode are formed in a single patterning process, they are formed with for example, a half tone mask process. With the half tone mask process, it is possible to adjust the exposure amount in different area films differently such that different area films have different shapes and different thicknesses. Exemplarily, after depositing a metal film on the active layer 10 and the insulating layer, the metal film is etched by regions with a half tone mask to obtain the second electrode 7 and the source/drain electrode 4 with different thicknesses.

It is to be understood that, the first electrode 6 in the thin film transistor may serve as a common electrode or a pixel electrode. When the first electrode serves as the common electrode, the corresponding second electrode 7 serves as the pixel electrode. Now, referring to FIG. 10, the manufacturing method for the corresponding thin film transistor includes following operations.

S1, providing a base substrate on which a first electrode and a gate electrode is formed respectively, such that the first electrode and the gate electrode are connected with each other.

S2, forming an insulating layer on the gate electrode and forming an active layer on the insulating layer.

S3, forming a source/drain electrode and a second electrode by a single patterning process on the active layer and the insulating layer respectively such that the source/drain electrode and the active layer are connected with each other and the second electrode and the source/drain electrode are connected with each other.

While forming the thin film transistor by the above-described method, the first electrode and the gate electrode may be formed by a single patterning process, the second electrode and the source/drain electrode may be formed by a single patterning process. In this way, with the manufacturing method of thin film transistor provided in embodiments of the present disclosure, it is possible to complete the preparation of the thin film transistor simply by two patterning processes. As compared to at least four patterning processes are needed to be implemented to complete the thin film transistor in the art, it is possible to reduce the number of patterning processes used in the manufacturing process of thin film transistor, simplify the manufacturing process thereof and improve the manufacturing efficiency.

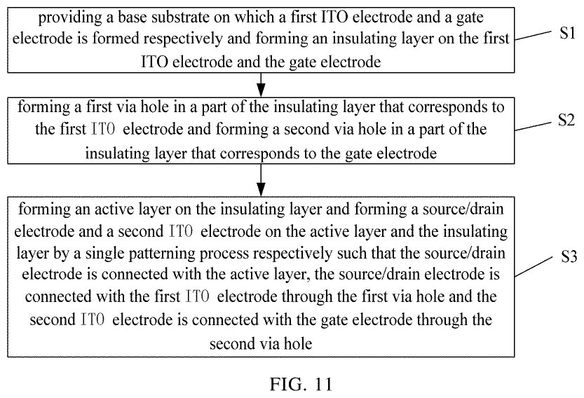

When the first electrode serves as the pixel electrode, the corresponding second electrode 7 serves as the common electrode. Now, referring to FIG. 11, the manufacturing method for the corresponding thin film transistor includes following operations.

S1, providing a base substrate on which a first electrode and a gate electrode is formed respectively and forming an insulating layer on the first electrode and the gate electrode.

S2, forming a first via hole in a part of the insulating layer that corresponds to the first electrode and forming a second via hole in a part of the insulating layer that corresponds to the gate electrode.

S3, forming an active layer on the insulating layer and forming a source/drain electrode and a second electrode on the active layer and the insulating layer by a single patterning process respectively such that the source/drain electrode is connected with the active layer, the source/drain electrode is connected with the first electrode through the first via hole and the second electrode is connected with the gate electrode through the second via hole.

By forming the thin film transistor with the above-described method, the first electrode and the gate electrode may be formed by a single patterning process and the first via hole and the second via hole may be formed by a single patterning process, the second electrode and the source/drain electrode may be formed by a single patterning process. In this way, in the manufacturing method of thin film transistor provided in embodiments of the present disclosure, it is possible to complete the preparation of the thin film transistor simply by three patterning processes. As compared to the manufacturing process in which at least four patterning processes are needed to be implemented to complete the thin film transistor in the art, it is possible to reduce the number of patterning processes used in the manufacturing process of thin film transistor, simplify the manufacturing process thereof and improve the manufacturing efficiency.

An embodiment of the present disclosure also provides an array substrate including the thin film transistor provided in the above-described embodiments. The thin film transistor in the array substrate has the same advantages as that in the above-described embodiments and will not be described in detail any more here.

An embodiment of the present disclosure also provides a display device including the array substrate provided in the above-described embodiment. The array substrate in the display device has the same advantages as that in the above-described embodiments and will not be described in detail any more here.

The display device provided in the above-described embodiment may be a product or component having display function, such as a mobile phone, a tablet computer, a notebook computer, a display, a TV set, a digital picture frame or a navigator.

The described above are only exemplary embodiments of the present disclosure, and the present disclosure is not intended to be limited thereto. For one of ordinary skill in the art, various changes and alternations may be readily contemplated without departing from the technical scope of the present disclosure, and all of these changes and alternations shall fall within the scope of the present disclosure.

1. A thin film transistor comprising: a first electrode, a gate electrode, an active layer, a source/drain electrode and a second electrode; wherein the source/drain electrode is connected with the active layer, the first electrode is provided oppositely to the second electrode; and the second electrode is provided in a same layer as the source/drain electrode.

2. The thin film transistor according to claim 1, wherein the second electrode and the source/drain electrode include a same material.

3. The thin film transistor according to claim 1, wherein the second electrode and the source/drain electrode both include metal.

4. The thin film transistor according to claim 1, wherein the first electrode is provided between the base substrate and the second electrode, the first electrode is a plate electrode or a slit electrode, and the second electrode is a slit electrode.

5. The thin film transistor according to claim 1, wherein when the first electrode is a plate electrode, the second electrode is a slit electrode, a slit direction of the slit electrode is along a long side of the plate electrode; or a slit direction of the slit electrode is along a short side of the plate electrode.

6. The thin film transistor according to claim 1, wherein the source/drain electrode has a thickness different from that of the second electrode.

7. The thin film transistor according to claim 1, wherein the source/drain electrode has a thickness of 0.35 μm˜0.4 μm; and the second electrode has a thickness of 0.04 μm˜0.07 μm.

8. The thin film transistor according to claim 1, wherein
the first electrode is a common electrode, and the second electrode is a pixel electrode;
the first electrode and the gate electrode are provided on the base substrate and are connected with each other, and an insulating layer is provided on the first electrode and the gate electrode; and
the active layer, the source/drain electrode and the second electrode are provided on the insulating layer respectively, and the second electrode is connected with the source/drain electrode.

9. The thin film transistor according to claim 1, wherein
the first electrode is a pixel electrode, and the second electrode is a common electrode;
the first electrode and the gate electrode are provided on the base substrate and an insulating layer is provided on the first electrode and the gate electrode;
a part of the insulating layer that corresponds to the first electrode is provided with a first via hole, and a part of the insulating layer that corresponds to the second electrode is provided with a second via hole; and
the active layer, the source/drain electrode and the second electrode are provided on the insulating layer, respectively, the source/drain electrode is connected with the first electrode through the first via hole, and the second electrode is connected with the gate electrode through the second via hole.

10. A manufacturing method of thin film transistor for manufacturing the thin film transistor according to claim 1, comprising forming a second electrode and a source/drain electrode by a single patterning process.

11. The manufacturing method of thin film transistor according to claim 10, wherein the second electrode and the source/drain electrode are formed in a single patterning process with a half tone mask.

12. The manufacturing method of thin film transistor according to claim 10, wherein
the first electrode is a common electrode, and the second electrode is a pixel electrode;
the manufacturing method of thin-film transistor further comprises:
providing a base substrate on which a first electrode and a gate electrode is formed respectively to allow the first electrode and the gate electrode to be connected with each other;
forming an insulating layer on the gate electrode and forming an active layer on the insulating layer; and
forming a source/drain electrode and a second electrode by a single patterning process on the active layer and the insulating layer respectively to allow the source/drain electrode and the active layer to be connected with each other and the second electrode and the source/drain electrode to be connected to each other.

13. The manufacturing method of thin film transistor according to claim 10, wherein
the first electrode is a pixel electrode, and the second electrode is a common electrode;
the manufacturing method of thin-film transistor further comprises:
providing a base substrate on which a first electrode and a gate electrode are formed respectively and forming an insulating layer on the first electrode and the gate electrode;
forming a first via hole in a part of the insulating layer that corresponds to the first electrode, and forming a second via hole in a part of the insulating layer that corresponds to the second electrode; and
forming an active layer on the insulating layer and forming a source/drain electrode and a second electrode on the active layer and the insulating layer by a single patterning process respectively to allow the source/drain electrode to be connected with the active layer, and allow the source/drain electrode to be connected with the first electrode through the first via hole and the second electrode to be connected with the gate electrode through the second via hole.

14. An array substrate comprising the thin film transistor according to claim 1.

15. A display device comprising the array substrate according to claim 14.

16. The thin film transistor according to claim 2, wherein the second electrode and the source/drain electrode both include metal.

17. The thin film transistor according to claim 4, wherein when the first electrode is a plate electrode, the second electrode is a slit electrode, a slit direction of the slit electrode is along a long side of the plate electrode; or a slit direction of the slit electrode is along a short side of the plate electrode.

18. The thin film transistor according to claim 17, wherein
the first electrode is a common electrode, and the second electrode is a pixel electrode;
the first electrode and the gate electrode are provided on the base substrate and are connected with each other, and an insulating layer is provided on the first electrode and the gate electrode; and
the active layer, the source/drain electrode and the second electrode are provided on the insulating layer respectively, and the second electrode is connected with the source/drain electrode.

19. The manufacturing method of thin film transistor according to claim 11, wherein
the first electrode is a common electrode, and the second electrode is a pixel electrode;
the manufacturing method of thin-film transistor further comprises:
providing a base substrate on which a first electrode and a gate electrode is formed respectively to allow the first electrode and the gate electrode to be connected with each other;
forming an insulating layer on the gate electrode and forming an active layer on the insulating layer; and
forming a source/drain electrode and a second electrode by a single patterning process on the active layer and the insulating layer respectively to allow the source/drain electrode and the active layer to be connected with each other and the second electrode and the source/drain electrode to be connected to each other.

20. The manufacturing method of thin film transistor according to claim 11, wherein
the first electrode is a pixel electrode, and the second electrode is a common electrode;
the manufacturing method of thin-film transistor further comprises:
providing a base substrate on which a first electrode and a gate electrode are formed respectively and forming an insulating layer on the first electrode and the gate electrode;
forming a first via hole in a part of the insulating layer that corresponds to the first electrode, and forming a second via hole in a part of the insulating layer that corresponds to the second electrode; and
forming an active layer on the insulating layer and forming a source/drain electrode and a second electrode on the active layer and the insulating layer by a single patterning process respectively to allow the source/drain electrode to be connected with the active layer, and allow the source/drain electrode to be connected with the first electrode through the first via hole and the second electrode to be connected with the gate electrode through the second via hole.
